(19) United States
(12) Patent Application Publication
(10) Pub. No.: US 2023/0066579 A1
(43) Pub. Date: Mar. 2, 2023

(54) ELECTRONIC CONTROL DEVICE WITH IMPROVED COOLING OF COMPONENTS

(71) Applicant: Hella GmbH & Co. KGaA, Lippstadt (DE)

(72) Inventors: Clement Tondellier, Toulouse (FR); Herve Gasc, Fonsorbes (FR); Helene Galaup, Toulouse (FR)

(21) Appl. No.: 18/045,334

(22) Filed: Oct. 10, 2022

Related U.S. Application Data
(63) Continuation of application No. PCT/EP2020/059981, filed on Apr. 8, 2020.

(51) Int. Cl. H05K 7/20

(52) U.S. Cl. CPC H05K 7/20409; H05K 7/20436; H05K 7/205; H05K 7/209

(57) ABSTRACT

An electronic control device (ECU) is provided for an electric power and/or steer by wire steering system (EPS). The ECU includes a printed circuit board (PCB) carrying electronic components, electronic components on a lower side and on an upper side of the PCB, a heat sink element on the lower side of the PCB, and a cover on the upper side of the PCB. At least one cooling track element is provided as an at least partly over-molded insert within the cover in order to conduct heat from at least one electronic component on the upper side of the PCB to the heat sink element on the lower side of the PCB and/or to the air outside of the ECU.

### CROSS REFERENCE

This application claims priority to and is a continuation of PCT Application No. PCT/EP2020/059981, filed Apr. 8, 2020, the entirety of which is hereby incorporated by reference.

### FIELD OF THE INVENTION

The invention is related to an electronic control device for an electric power and/or steer by wire steering system according to the independent device claim. Furthermore, the invention is related to a corresponding electric power and/or steer by wire steering system for an electrical and/or autonomous vehicle according to the secondary independent device claim.

### BACKGROUND OF THE INVENTION

Electronic control devices are basically known. Electronic control devices usually comprise a printed circuit board carrying electronic components (hereinafter referred to as electronic components) being attached to a lower side and to an upper side of the printed circuit board. Electronic control devices also comprise heat sink element, basically in form of metal plates, positioned on the lower side of the printed circuit board. The cooling of the electronic components being attached to the upper side (that is wrong side) of the printed circuit board can be than insufficient. If there are components to cool down on both sides of the PCB, two heat sink elements on both sides of the printed circuit board can be provided. However, this solution can have space disadvantages.

### SUMMARY OF THE INVENTION

The aim of the present invention is to provide an electronic control device for an electric power and/or steer by wire steering system having an improved cooling mechanism for all electronic components being attached to the lower side and to the upper side of the printed circuit board. Furthermore, the aim of the present invention is to provide a corresponding electric power and/or steer by wire steering system for an electrical and/or autonomous vehicle.

The invention provides according to the first aspect an electronic control device for an electric power and/or steer by wire steering system. The invention provides according to the second aspect a corresponding electric power and/or steer by wire steering system for an electrical and/or autonomous vehicle. Features and details, which are described in connection with individual aspects of the invention, are of course also valid in connection with the other aspects of the invention and vice versa.

The invention provides according the first aspect an electronic control device for an electric power and/or steer by wire steering system, comprising a printed circuit board carrying electronic components (in the later text also named simply components) on a lower side and an upper side of the printed circuit board, a heat sink element (for example metal plate) on the lower side of the printed circuit board, and a cover on the upper side of the printed circuit board. The invention provides at least one (or more than one) cooling track element (for example metallic insert) as an at least partly over-molded insert within the cover in order to conduct heat from at least one electronic component on the upper side of the printed circuit board to the heat sink element on the lower side of the printed circuit board and/or to the air (or environment) outside of the electronic control device. The number of cooling track elements can be adapted to the number of the components need to be cooled down.

The idea of the invention is that the components, which are not on the heat sink side of the printed circuit board by transferring the heat via metallic inserts over-molded in a plastic part in the cover. The metallic inserts can be connected to the heat sink element. The contact to the heat sink element can be done as a direct contact or with thermal paste (that is terminal interface material). Additionally or alternatively, the metallic inserts can be passed through the material of the cover to the outside of the electronic control device into the environment. Thus, the cooling track elements can allow thermal exchanges with the heat sink element and/or with the external air.

The invention enables to save construction space (no additional heat sink element). The invention provides a cost effective and simple possibility to put cooling track elements to cool down components on both sides of the printed circuit board. Thus, effective cooling can be provided on areas that are not in contact with the heat sink element or other metallic parts.

Furthermore, the invention may provide by an electronic control device that the heat sink element comprises metal material, ceramic, Carbon, electrically conductive plastic and/or electrically conductive fiber. This the flexibly by construction of the heat sink element can be improved.

Moreover, the invention may provide by an electronic control device that the heat sink element is provided at least partly in form of a plate and/or a shell. The heat sink element in form of a plate can be cost effective and simple element. Especially with the combination of the inventive cooling track element, complicated geometries of the heat sink element can be avoided. The heat sink element in form of a shell can be advantageous to form a housing part for elements of the electronic control device.

Further, the invention may provide by an electronic control device that the heat sink element forms a lower housing part. In this case, a compact electronic control device can be provided. Thus, the heat sink element can conduct the heat directly to the environment.

According to a further advantage of the invention, the cover can comprise organic and/or inorganic plastic material. Thus sealing of the elements of the electronic control device can be provided. Also, the weight of the electronic control can be reduced.

Furthermore, the invention may provide by an electronic control device that the cover is provided at least partly in form of a shell, especially to provide encapsulated space for the elements of the electronic control device. Thus, the construction of the electronic control device can be simplified.

Moreover, the invention may provide by an electronic control device that the at least one cooling track element comprises metal material, ceramic, Carbon, electrically conductive plastic and/or electrically conductive fiber. This the flexibly by construction of the cooling track element can be improved.

Further, the invention may provide by an electronic control device that electronic components (or simply components) comprise at least one capacitor, at least one resistor, especially at least one shunt resistor, at least one transistor, especially at least one field effect transistor, and/or at least one coil. Thus, various applications designs of the electronic control device can be provided.

In addition, the invention may provide by an electronic control device that the heat sink element comprises at least one heat sink (bulk) protrusion extending perpendicularly from the upper side of the heat sink element. Thus, transition points to the heat sink element may be created to facilitate the interconnection of the cooling track element.

Furthermore, the invention may provide by an electronic control device that the at least one cooling track element comprises a, especially uninterrupted and/or uniform, thermal connection section (for example angle- or hook-shaped) for connecting the at least one electronic component on the upper side of the printed circuit board directly or by means of thermal interface material. In this way, the heat can be effectively absorbed by the cooling track element in order to transfer away from the corresponding component.

Moreover, the invention may provide by an electronic control device that the at least one cooling track element comprises a, especially uninterrupted and/or uniform, track section (for example flexible) for conducting heat from the at least one electronic component on the upper side of the printed circuit board to the heat sink element on the lower side of the printed circuit board and/or to the air outside of the electronic control device. In this way, the heat can be effectively transported away from the corresponding component.

Furthermore, the invention may provide by an electronic control device that the at least one cooling track element comprises a, especially uninterrupted and/or uniform, first thermal forwarding section for connecting the heat sink element on the lower side of the printed circuit board directly or by means of thermal interface material. Thus, the transport of the heat to the heat sink element can be provided.

Advantageously the invention may provide by an electronic control device that the at least one cooling track element comprises a, especially uninterrupted and/or uniform, second thermal forwarding section for connecting the air outside of the electronic control device. Thus, the transport of the heat to the environment can be provided.

The first thermal forwarding section and the second thermal forwarding section can be used together or alternatively.

Furthermore, the invention may provide by an electronic control device that the thermal connection section is provided at least partly in form of a plate or disk. Thus, a simple and effective element can be provided to absorb the heat on the at least one electronic component.

Further, the invention may provide by an electronic control device that the track section is provided at least partly in form of a wall or stripe. Thus, a simple and effective element can be provided to transfer heat over the cooling track element.

Moreover, the invention may provide by an electronic control device that the first thermal forwarding section is provided at least partly in form of a sleeve or cylinder. Thus, the connection to the heat sink element can be improved.

In addition, the invention may provide by an electronic control device that the second thermal forwarding section is provided at least partly in form of a plate or disk. Thus, an effective dissipation of heat to the environment can be provided.

An electric power and/or steer by wire steering system for an electrical and/or autonomous vehicle represents the second aspect of the invention, comprising an electronic control device, which can be designed as described before. With help of the inventive electric power and/or steer by wire steering system the same advantages can be achieved as with help of the inventive electronic control device described above. Full reference is made to these advantages in the present case.

### BRIEF DESCRIPTION OF THE DRAWINGS

Reference is now made more particularly to the drawings, which illustrate the best presently known mode of carrying out the invention and wherein similar reference characters indicate the same parts throughout the views.

FIG. 1 shows a sample of an electronic control device known from the state of the art.

FIG. 2 shows an electronic control device according to invention.

FIG. 3 shows an electronic control device according to invention.

FIG. 4 is a view on a cover from the inside of the electronic control device according to invention.

### DETAILED DESCRIPTION OF THE INVENTION

In the different figures, identical elements always have the same reference signs, which are usually only described once.

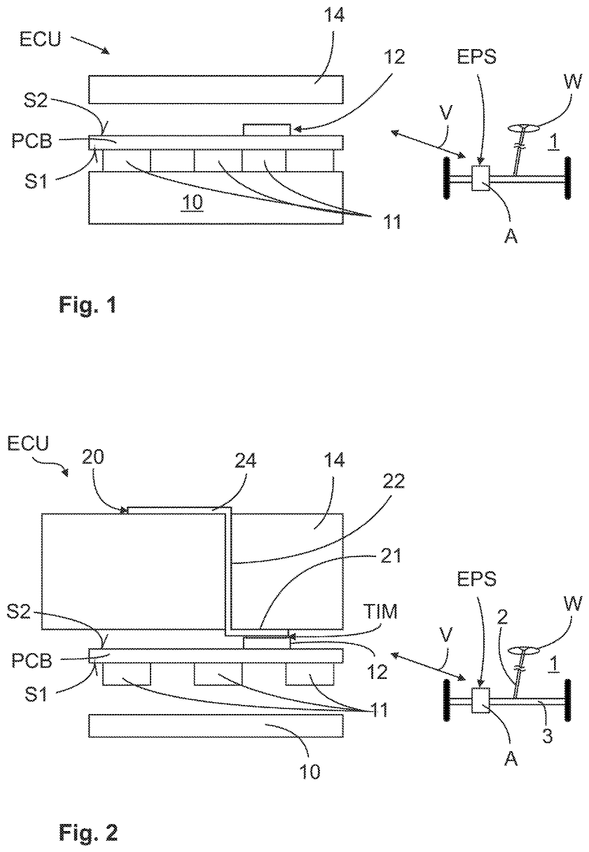

An exemplary electronic control devices ECU known from the state of the art is shown in FIG. 1. As FIG. 1 shows, the electronic control device ECU comprise a printed circuit board PCB carrying electronic components 11, 12 attached to a lower side S1 and to an upper side S2 of the printed circuit board PCB. Electronic control device ECU also comprise heat sink element 10, for example in form of metal plate, positioned on the lower side S1 of the printed circuit board PCB. The cooling of the electronic components 12 being attached to the upper side S2 of the printed circuit board PCB can be not effective, since the heat should to be transported over the air within the inner space of the electronic control device ECU. To provide effective cooling of all components 11, 12 up and down regarding to the printed circuit board PCB two heat sink elements 10 can be provided on both sides of the printed circuit board PCB. However, this solution can have space and weight disadvantages.

The invention provides an improved electronic control device ECU shown in the FIGS. 2 to 4, configured for an electric power and/or steer by wire steering system EPS. The electric power and/or steer by wire steering system EPS is shown only schematically for simplicity grounds. The electric power and/or steer by wire steering system EPS can be electric power steering system EPS which helps a driver to steer a vehicle 1 by augmenting steering effort needed to turn the steering wheel W. The electric power and/or steer by wire steering system EPS can also use electrical or electro-mechanical systems for performing vehicle steering functions without mechanical linkages between the steering wheel W and the steering axle 2 or directly to the driving axle 3 of the vehicle 1. The steering system EPS according to invention can be used for both variants (power steering system and steer by wire steering system) or for a combination of this variants. The electronic control device ECU according to the invention can receive and analyze signals from velocity sensors and/or torque sensors (not shown for simplicity grounds) attached to the steering axle 2 of the vehicle 1 and provide corresponding control signals over a (wireless or wired) communication line V to the actuator A on the steering axle 2 or directly on the driving axle 3.

The inventive electronic control device ECU is provided with an improved cooling mechanism for all electronic components 11, 12 being attached to the lower side S1 and to the upper side S2 of the printed circuit board PCB. A corresponding electric power and/or steer by wire steering system EPS for an electrical and/or autonomous vehicle 1 builds the second aspect of the invention.

The electronic control device ECU according to FIGS. 2 to 4 comprise a printed circuit board PCB carrying electronic components 11, 12 (in the later text also named simply components 11, 12) on a lower side S1 and an upper side S2 of the printed circuit board PCB, a heat sink element 10 (for example metal plate) on the lower side S1 of the printed circuit board PCB, and a cover 14 on the upper side S2 of the printed circuit board PCB.

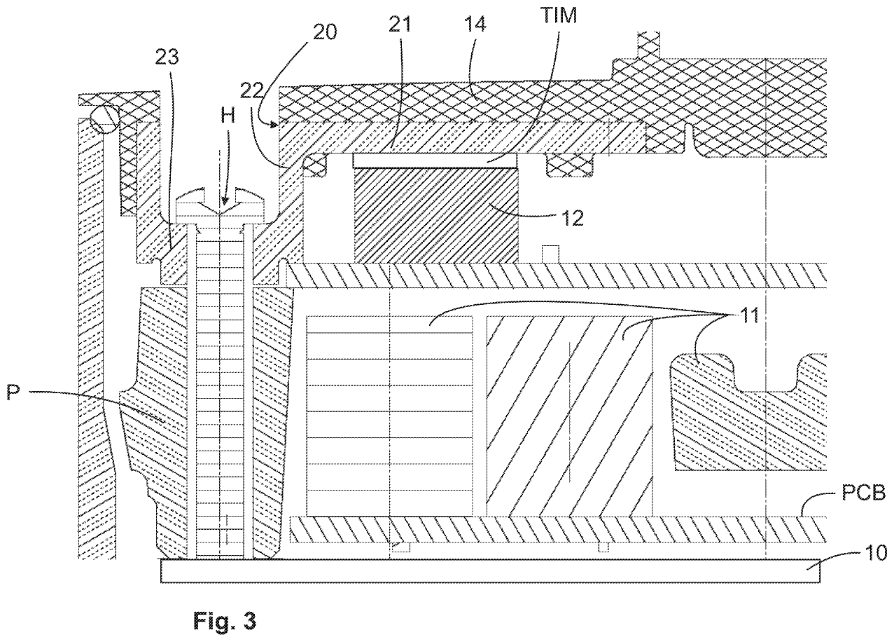

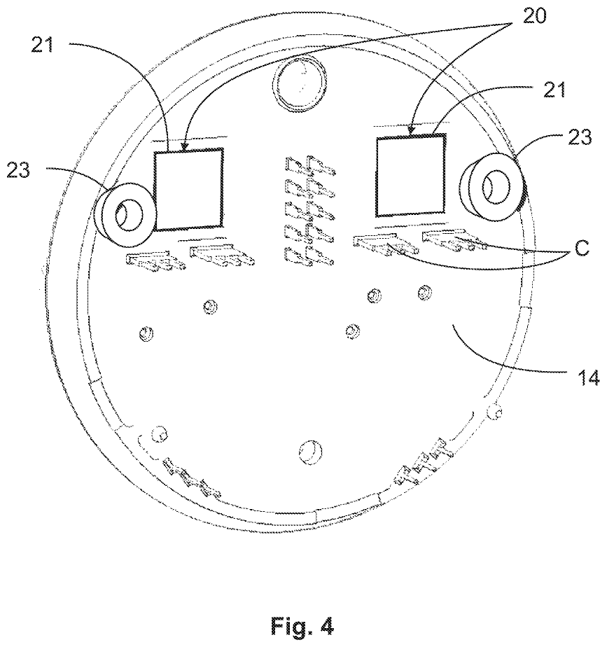

As the FIGS. 2 to 4 show, at least one cooling track element 20 is provided as an at least partly over-molded insert within the cover 14 in order to conduct heat Q′ from at least one electronic component 12 on the upper side S2 of the printed circuit board PCB to the heat sink element 10 on the lower side S1 of the printed circuit board (see FIGS. 3 and 4) and/or to the air (or environment) outside of the electronic control device ECU (see FIG. 2).

Also a combination of heating paths to the heat sink element 10 on the lower side S1 of the printed circuit board (see FIGS. 3 and 4) and to the air (or environment) outside of the electronic control device ECU (see FIG. 2) is possible according to the invention. This combination is not shown in the figures for the simplicity grounds, but described in details below.

Thus, the components 12, which are not on the heat sink 10 side S1 of the printed circuit board PCB, can be cooled down by transferring the heat via corresponding cooling track elements 20 over-molded in a plastic part in the cover 20. For each component 12, which should be cooled down a corresponding cooling track element 20 can be provided.

The contact the cooling track elements 20 to the heat sink element 10 in FIG. 3 can be done as a direct contact or with terminal interface material TIM. Additionally or alternatively, the cooling track elements 20 can be passed through the material of the cover 20 to the outside of the electronic control device ECU into the environment. Thus, the cooling track elements 20 can allow thermal exchanges with the heat sink element 10 and/or the external air.

The electronic components 11, 12 can comprise at least one capacitor, at least one resistor, especially at least one shunt resistor, at least one transistor, especially at least one field effect transistor, and/or at least one coil.

The heat sink element 10 as well as cooling track elements 20 can comprise metal material, ceramic, Carbon, electrically conductive plastic and/or electrically conductive fiber.

The heat sink element 10 can be provided at least partly in form of a plate and/or a shell. According to one of possible advantages of the invention, the heat sink element 10 can form a lower housing part for the electronic control device ECU. In this case a compact electronic control device ECU can be provided, whereas the heat sink element 10 can conduct the heat Q′ directly to the environment through its lower side.

The cover 14 can comprise organic and/or inorganic plastic material. The cover 14 is provided at least partly in form of a shell, especially to provide encapsulated and/or sealed space for the elements of the electronic control device ECU.

As FIG. 3 schematically shows, the heat sink element 10 can comprise at least one heat sink protrusion P extending perpendicularly from the upper side of the heat sink element 10 to facilitate the interconnection of the cooling track element 20. The heat sink protrusion P can have a hole H to improve the heat Q′ exchange with the environment.

As FIGS. 2 and 3 show, the at least one cooling track element 20 can comprise a, especially uninterrupted and/or uniform, thermal connection section 21 (for example angle- or hook-shaped) for connecting the at least one electronic component 12 on the upper side S2 of the printed circuit board PCB directly or by means of thermal interface material TIM.

As FIGS. 2 and 3 show, the at least one cooling track element 20 can comprise a, especially uninterrupted and/or uniform, track section 22 (for example flexible) for conducting heat Q′ from the at least one electronic component 12 on the upper side S2 of the printed circuit board PCB to the heat sink element 10 on the lower side S1 of the printed circuit board PCB and/or to the air outside of the electronic control device ECU.

As FIG. 3 shows, the at least one cooling track element 20 can comprise a, especially uninterrupted and/or uniform, first thermal forwarding section 23 for connecting the heat sink element 10 directly or by means of thermal interface material TIM. Thus, the transport of the heat to the heat sink element can be provided.

As FIG. 2 shows, the at least one cooling track element 20 can comprise a, especially uninterrupted and/or uniform, second thermal forwarding section 24 for connecting the air outside of the electronic control device ECU.

The first thermal forwarding section 23 and the second thermal forwarding section 24 can be used together or alternatively in order to conduct heat Q′ from the at least one electronic component 12 on the upper side S2 of the printed circuit board PCB to the heat sink element 10 on the lower side S1 of the printed circuit board (see FIGS. 3 and 4) and/or to the air (or environment) outside of the electronic control device ECU (see FIG. 2).

As FIGS. 2 and 3 indicate, the thermal connection section 21 can be provided at least partly in form of a plate or disk.

As FIGS. 2 and 3 indicate, the track section 22 can be provided at least partly in form of a wall or stripe.

As FIG. 3 indicates, the first thermal forwarding section 23 can be provided at least partly in form of a sleeve or cylinder. The sleeve or cylinder can correspond to the heat sink protrusion P with the hole H to improve the heat Q′ exchange with the environment.

As FIG. 2 indicates, the second thermal forwarding section 24 can be provided at least partly in form of a plate or disk.

As FIG. 4 indicates, the cover 20 can include connectors/pins C for power supply and connection to electronic components 11, 12 of the electronic control device ECU. The connectors C can also be at least partly over-molded with the plastic material of the cover 20.

The invention enables to save construction space (no additional heat sink element) of the electronic control device ECU. The invention provides a cost effective and simple possibility to put cooling track elements 20 to cool down components 11, 12 on both sides S1, S2 of the printed circuit board PCB. Thus, effective cooling can be provided on areas that are not in contact with the heat sink element 10 or other metallic parts of the electronic control device ECU.

The preceding description of the figures describes the present invention within the framework of examples. Of course, individual features of the embodiments can be freely combined with each other, provided it is technically reasonable, without leaving the scope of the invention.

### REFERENCE LIST

1 vehicle
2 steering axle
3 driving axle
10 heat sink element
11 electronic component
12 electronic component
14 cover
20 cooling track element
21 thermal connection section
22 track section
23 first thermal forwarding section
24 second thermal forwarding section
A actuator
H hole
ECU electronic control device
PCB printed circuit board
P protrusion
CY heat
S1 lower side
S2 upper side
TIM thermal interface material
V communication and/or control line

1. An electronic control device (ECU) for an electric power and/or steer by wire steering system (EPS), the ECU comprising:
a printed circuit board (PCB) carrying electronic components,
one or more electronic components on a lower side of the PCB,
one or more electronic components on an upper side of the PCB,
a heat sink element on the lower side of the PCB,
a cover on the upper side of the PCB, and
at least one cooling track element provided as an at least partly over-molded insert within the cover to conduct heat from at least one electronic component on the upper side of the PCB to the heat sink element on the lower side of the PCB and/or to the air outside of the ECU.

2. The ECU according to claim 1, wherein the heat sink element comprises metal material, ceramic, carbon, electrically conductive plastic and/or electrically conductive fiber, and/or the heat sink element is provided at least partly in form of a plate and/or a shell, and/or the heat sink element forms a lower housing part.

3. The ECU according to claim 1, wherein the cover comprises organic and/or inorganic plastic material, and/or the cover is provided at least partly in form of a shell.

4. The ECU according to claim 1, wherein the at least one cooling track element comprises metal material, ceramic, carbon, electrically conductive plastic and/or electrically conductive fiber.

5. The ECU according to claim 1, wherein the electronic components comprise at least one capacitor, at least one resistor, especially at least one shunt resistor, at least one transistor, and/or at least one coil.

6. The ECU according to claim 1, wherein the heat sink element comprises at least one heat sink protrusion extending perpendicularly from the upper side of the heat sink element.

7. The ECU according to claim 1, wherein the at least one cooling track element comprises a thermal connection section for connecting the at least one electronic component on the upper side of the PCB directly or via thermal interface material (TIM).

8. The ECU according to claim 1, wherein the at least one cooling track element comprises a track section for conducting heat from the at least one electronic component on the upper side of the PCB to the heat sink element on the lower side of the PCB and/or to the air outside of the ECU.

9. The ECU according to claim 1, wherein the at least one cooling track element comprises a first thermal forwarding section for connecting the heat sink element on the lower side of the PCB directly or via TIM.

10. The ECU according to claim 1, wherein the at least one cooling track element comprises a second thermal forwarding section for connecting the air outside of the ECU.

11. The ECU according to claim 1, wherein the thermal connection section is provided at least partly in form of a plate or disk.

12. The ECU according to claim 1, wherein the track section is provided at least partly in form of a wall or stripe.

13. The ECU according to claim 1, wherein the first thermal forwarding section is provided at least partly in form of a sleeve or cylinder.

14. The ECU according to claim 1, wherein the second thermal forwarding section is provided at least partly in form of a plate or disk.

15. An electric power and/or steer by wire steering system (EPS) for an electrical and/or autonomous vehicle, the EPS comprising an ECU according to claim 1.
